(19) United States
(12) Patent Application Publication
(10) Pub. No.: US 2015/0187925 A1
(43) Pub. Date: Jul. 2, 2015

(54) ENHANCEMENT-MODE DEVICE

(71) Applicant: Enkris Semiconductor, Inc., Jiangsu (CN)

(72) Inventor: Kai Cheng, Jiangsu (CN)

(73) Assignee: Enkris Semiconductor, Inc., Jiangsu (CN)

(21) Appl. No.: 14/143,736

(22) Filed: Dec. 30, 2013

(51) Int. Cl. H01L 29/778; H01L 29/205; H01L 29/201; H01L 29/423; H01L 29/20; H01L 29/51

(52) U.S. Cl. CPC H01L 29/7787; H01L 29/2003; H01L 29/518; H01L 29/517; H01L 29/51; H01L 29/201; H01L 29/42376; H01L 29/205

(57) ABSTRACT

An enhancement-mode device is provided. A spontaneous polarization effect and a piezoelectric effect in a crystal of nitride are greatest in a <0002> direction and do not exist or are minimal in a non-polar and a semi-polar direction, which is used to form the enhancement-mode device. A groove having a non-polar surface or a semi-polar surface is formed in an epitaxial multilayer structure, thereby interrupting two-dimensional electron gas in the groove. When a gate voltage is increased, the electron density on the non-polar and semi-polar surfaces in the groove is increased consequently, thereby realizing an enhancement-mode operation.

### FIELD OF THE DISCLOSURE

The present disclosure generally relates to microelectronic technology, and more particularly, to an enhancement-mode device.

### BACKGROUND OF THE DISCLOSURE

Gallium nitride (GaN) as a third generation semiconductor material has a wide bandgap, a high saturated electron drift velocity, a great breakdown field strength and good thermal conductivity. Compared with silicon and gallium arsenide, the GaN material is more suitable for manufacturing a semiconductor device of high temperature, high frequency, high voltage and high power.

Since an AlGaN (aluminum gallium nitride)/GaN heterojunction has high-density two-dimensional electron gas (2DEG), a high electron mobility transistor formed with the AlGaN/GaN heterojunction is generally a depletion-mode device but hardly an enhancement-mode (E-mode) device. However, applications of a depletion-mode (D-mode) device are limited. For example, an enhancement-mode (normally-off) switch device is needed in a power switch device. An enhancement-mode GaN switch device is mainly used in a high frequency device, a power switch device, a digital circuit etc., thus, research on the enhancement-mode GaN switch device is significant.

To form an enhancement-mode GaN switch device, to take appropriate measures to reduce carrier density beneath the gate when the gate voltage is zero is required. In conventional technologies, a first method includes using an etching process for gate recess and partially thinning AlGaN layer under the gate to control or reduce the 2DEG density under the gate. Referring to FIG. 1, a buffer layer 11, a GaN layer 12 and an AlGaN layer 13 are formed on a substrate 10. A gate 14, a source electrode 15 and a drain electrode 16 are located on the AlGaN 13. The AlGaN layer 13 under the gate 14 is partially etched, thereby reducing a thickness of the AlGaN layer 13 under the gate 14. A second method includes: selectively reserving p-type AlGaN or p-type GaN under a gate to pull up the conduction band at an AlGaN/GaN heterojunction, thereby forming an enhancement-mode device. Referring to FIG. 2, a portion of p-type nitride 17 is reserved under a gate 14′. A third method includes incorporating negatively charged fluorine ions into the barrier layer and positively shift the threshold voltage. Referring to FIG. 3, negatively charged fluorine ions are injected into the barrier layer 13 beneath the gate 14′.

However, all the above methods have some disadvantages. In the first method, a threshold voltage is within the range from 0V to 1V, which does not reach an applicative threshold voltage ranging from 3V to 5V. To reach a relatively high threshold voltage and an operating voltage, an extra dielectric layer is needed, such as Aluminum Oxide (Al₂O₃) deposited by atomic layer deposition (ALD). However, how to control an interface state between the dielectric layer and the AlGaN layer becomes a severe problem to be solved. In the second method, all the regions expect a region under the gate are required to be etched selectively. How to accurately control an etched thickness is quite challenging. Besides, defect caused by the etching process and remained magnesium atoms in p-type AlGaN may result in serious current collapse. Furthermore, the 2DEG density in the AlGaN/GaN hetero junction may be greatly limited because of a low hole density (generally, a hole density of p-type GaN is not greater than 1E18/cm³). If the 2DEG density is too high, an enhancement-mode device cannot be realized. Generally, aluminum composition is less than 0.2, such as 0.15, in an AlGaN/GaN heterojunction in an enhancement-mode device. In the third method, a fluoride plasma processing may destroy a lattice structure and it is difficult to repetitive control processes, which may severely affect the stability and reliability of the device.

### SUMMARY

As described in background, when an enhancement-mode device employs a GaN material, it is necessary to control a carrier density in a channel when a gate voltage is zero. However, in conventional technologies, any one of the above three methods including thinning a thickness of a nitride barrier layer under a gate, reserving a p-type nitride layer under the gate and injecting negatively charged ions into the nitride barrier layer has great impact on the stability and reliability of device because of process problems.

Therefore, in the present disclosure, an enhancement-mode device is provided, wherein 2DEG is controlled based on a theory that group III nitride is a polar semiconductor. Referring to FIGS. 4 and 5, different from traditional group III-V semiconductors, group III nitride has a strong built-in electrical field therein. When an AlInGaN/GaN hetero junction is formed in a C-plane (0002), 2DEG with a high electron density may be generated in the AlInGaN/GaN hetero junction even without n-type doping in an AlInGaN barrier layer. The reason is that, a 2DEG density may exceed 1E13/cm² because of a spontaneous polarization electric field and a piezoelectric field caused by stress in the group III nitride. However, the spontaneous polarization electric field and the piezoelectric field only exist in the <0002> direction but not in a non-polar direction, i.e., a direction perpendicular to the <0002> direction, such as <1-100> direction, <11-20> direction etc. In the semi-polar direction, such as a direction between <0002> direction and <1-100> direction or <11-20> direction, the built-in field is far less than a built-in electric field of the <0002> direction.

Therefore, in a GaN hetero junction growing along the polar direction, 2DEG with a high electron density can be generated without doping. However, since no polarization electric field is on the non-polar surface or semi-polar surface of the GaN material or only low polarization electric field is thereon, no 2DEG will be generated on the non-polar surface or semi-polar surface without doping. In the present disclosure, non-planar structure is formed in a gate region. Specifically, a groove is formed in the gate region. A non-polar surface of nitride, a semi-polar surface of nitride or a combination of them in the groove can interrupt 2DEG in a gate region, thereby realizing an enhancement-mode device.

To sum up, a groove is formed during manufacturing the enhancement-mode device. A non-polar surface or a semi-polar surface in the groove can interrupt 2DEG. A plasma etching process is not required to be performed to a nitride barrier layer, thereby avoiding degradation in performance caused by damage of an active region, such as a low current density or a current collapse effect. Further, no magnesium atom is needed to form p-type nitride, thereby avoiding pollution to a Metal-organic Chemical Vapor Deposition (MOCVD) chamber or a Molecular Beam Epitaxy (MBE) chamber.

In an embodiment, an enhancement-mode device which is an epitaxial multilayer structure formed on a substrate may be provided, including:

a nitride channel layer and a nitride barrier layer successively formed on the substrate;

a groove formed in the epitaxial multilayer structure;

a groove having a non-polar surface or a semi-polar surface formed in the epitaxial multilayer structure, resulting in at least a portion of two-dimensional electron gas in the epitaxial multilayer structure being interrupted;

a gate region defined by the groove and two Ohmic contact regions, wherein the two Ohmic contact regions are on two opposite sides of the gate region;

a gate formed in the gate region; and

a source electrode and a drain electrode in the two Ohmic contact regions.

Optionally, the enhancement-mode device may further include a dielectric layer formed on the nitride barrier layer.

Optionally, the dielectric layer may include one selected from silicon nitride, silicon carbon nitride, silicon dioxide, silicon aluminum nitride, aluminum oxide, aluminum oxynitride, silicon oxynitride and hafnium oxide, or any combination thereof.

Optionally, the epitaxial multilayer structure may further include a nitride cap layer formed on the nitride barrier layer, the nitride cap layer including gallium nitride or aluminum gallium nitride.

Optionally, an aluminum nitride layer may be formed between the nitride channel layer and the nitride barrier layer.

Optionally, a section of the groove may take a shape of rectangle, triangle, trapezoid, serration, polygon, semicircle, “U” shape, or any combination of them.

Optionally, a nitride nucleation layer and/or a nitride buffer layer may be formed on the substrate.

Optionally, the substrate may include sapphire, silicon carbide, silicon, lithium niobate, silicon on insulator, gallium nitride or aluminum nitride.

In the present disclosure, a plasma etching process is not required to be performed to the barrier layer, thereby avoiding degradation in performance caused by damage of an active region, such as low current density or a current collapse effect. Further, no magnesium atom is needed to form p-type nitride, thereby avoiding pollution to a MOCVD chamber or a MBE chamber.

### BRIEF DESCRIPTION OF THE DRAWINGS

FIG. 1 schematically illustrates a cross-sectional view of an enhancement-mode device in the prior art, which is realized by thinning a thickness of an AlGaN layer under a gate to control or reduce a 2DEG density under the gate;

FIG. 2 schematically illustrates a cross-sectional view of an enhancement-mode device in the prior art, which is realized by selectively reserving a portion of p-type AlGaN/GaN under a gate to pull up a conduction band energy level at an AlGaN/GaN hetero junction and form a consumption region;

FIG. 3 schematically illustrates a cross-sectional view of an enhancement-mode device in the prior art, which is realized by fluoride plasma processing under a gate;

FIG. 4 schematically illustrates a diagram of a lattice structure of a nitride;

FIG. 5 schematically illustrates a distribution diagram of built-in field in different directions in a nitride;

FIG. 6 schematically illustrates a cross-sectional view of an enhancement-mode device according to an embodiment of the present disclosure;

FIG. 7 schematically illustrates a cross-sectional view of an enhancement-mode device according to another embodiment of the present disclosure;

FIG. 8 schematically illustrates a cross-sectional view of an enhancement-mode device according to another embodiment of the present disclosure, wherein a groove in a gate region of the enhancement-mode device has a triangular cross-section;

FIG. 9 schematically illustrates a cross-sectional view of an enhancement-mode device according to another embodiment of the present disclosure, wherein a groove in a gate region of the enhancement-mode device has a trapezoidal cross-section;

FIG. 10 schematically illustrates a cross-sectional view of an enhancement-mode device according to another embodiment of the present disclosure, wherein a section of a groove in a gate region takes a shape of a combination of a rectangle and a trapezoid;

FIG. 11 schematically illustrates a cross-sectional view of an enhancement-mode device according to another embodiment of the present disclosure, wherein a groove in a gate region of the enhancement-mode device has a semicircular cross-section;

FIG. 12 schematically illustrates a cross-sectional view of an enhancement-mode device according to another embodiment of the present disclosure, wherein a groove in a gate region of the enhancement-mode device has a “U” shaped cross-section;

FIG. 13 schematically illustrates a cross-sectional view of an enhancement-mode device according to another embodiment of the present disclosure;

FIG. 14 schematically illustrates a cross-sectional view of an enhancement-mode device according to another embodiment of the present disclosure; and

FIG. 15 schematically illustrates a cross-sectional view of an enhancement-mode device according to another embodiment of the present disclosure.

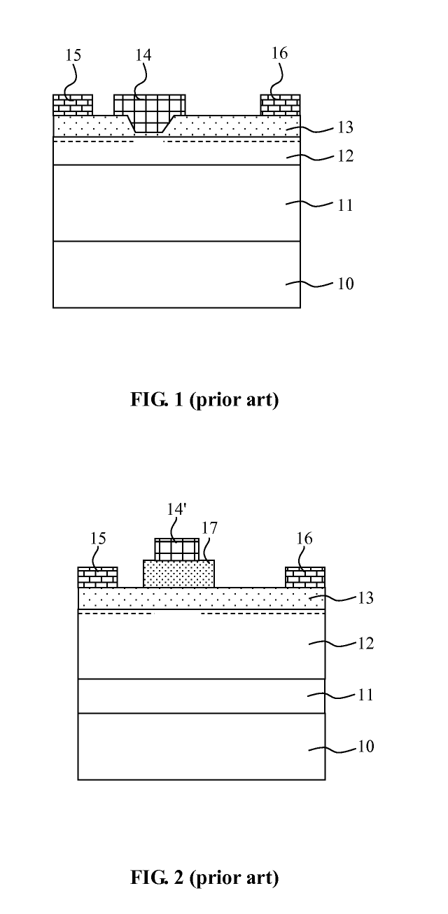

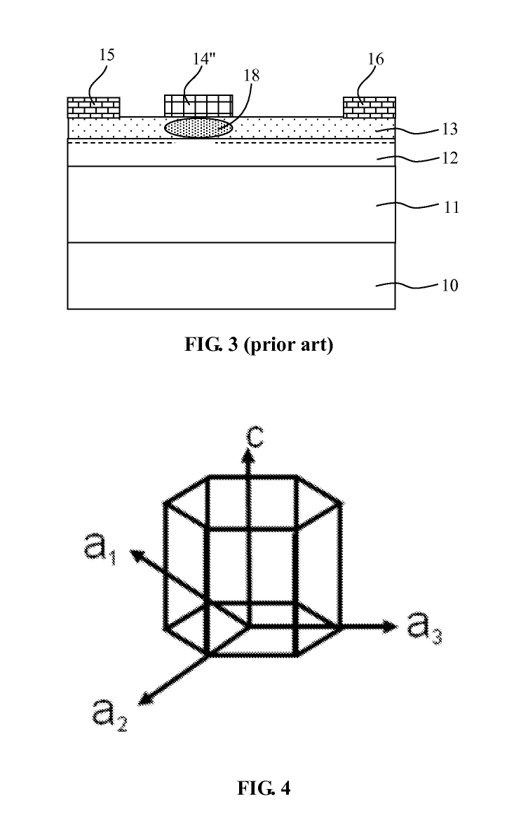

### DETAILED DESCRIPTION OF THE DISCLOSURE

In order to clarify the objects, characteristics and advantages of the disclosure, embodiments of present disclosure will be described in detail in conjunction with accompanying drawings.

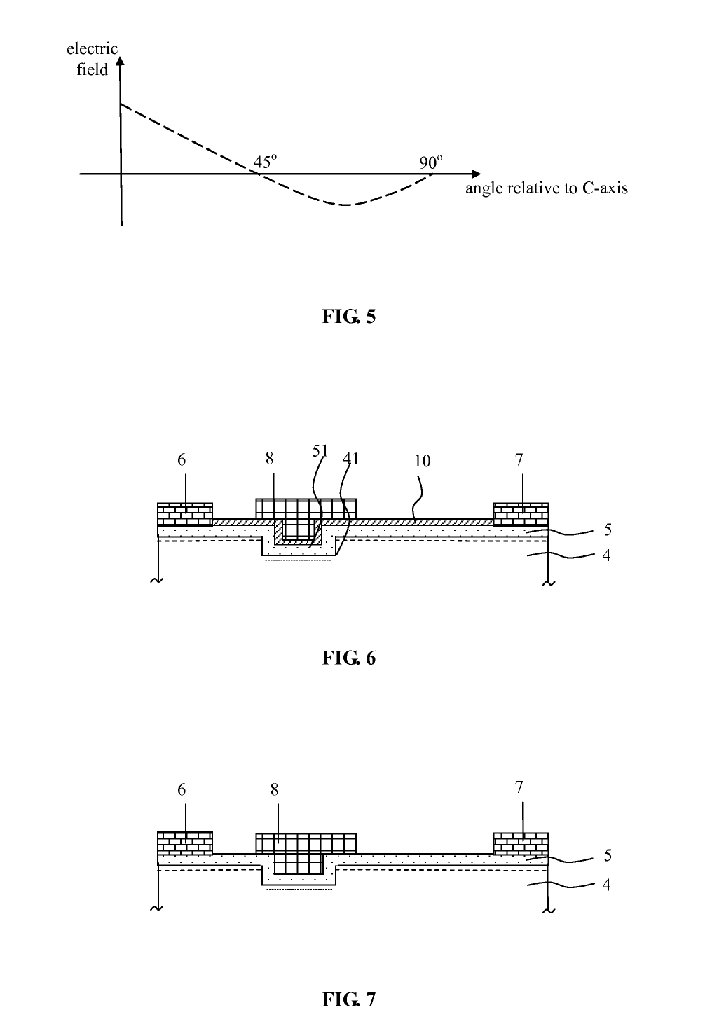

FIG. 6 schematically illustrates a cross-sectional view of an enhancement-mode device according to an embodiment of the present disclosure. As shown in FIG. 6, the enhancement-mode device is an epitaxial multilayer structure formed on a substrate. The broken line in FIG. 6 represents that the substrate under the epitaxial multilayer structure may take any suitable shape.

In some embodiments, the substrate may include sapphire, silicon carbide (SiC), silicon, lithium niobate (LiNbO₃), silicon on insulator (SOI), GaN or aluminum nitride (AlN). Other layers, such as a nitride nucleation layer and/or a nitride buffer layer, may be formed on the substrate to be used to deposit a nitride semiconductor device. In some embodiments, the nitride nucleation layer may include AlN, GaN, AlGaN and etc. The nitride buffer layer may include AlGaN. The epitaxial multilayer structure may include a nitride channel layer 4, a nitride barrier layer 5 and a dielectric layer 10 successively formed on the substrate. A gate region and two Ohmic contact regions are formed on the epitaxial multilayer structure and the two Ohmic contact regions are on two opposite sides of the gate region. The gate region is adapted to deposit a gate 8 and the two Ohmic contact regions are adapted to deposit a source electrode 6 and a drain electrode 7.

In some embodiments, the nitride channel layer 4 may include GaN. A groove 41 is formed on the nitride channel layer 4, which defines the location of the gate region. According to the spontaneous polarization effect and piezoelectric effect of group III nitride, a surface of the nitride channel layer 4 is a polar surface, i.e. (0002) surface. While, at least two side surfaces of the groove 41 have an angle with the surface of the nitride channel layer 4, that is, the at least two side surfaces are located in a non-<0002> direction, such as a (1-100) surface, (11-20) surface, (1-101) surface, (11-22) surface etc.

In some embodiments, a groove 51 is formed on a portion of the nitride barrier layer 5 which is located above the groove 41 and defined by the groove 41. The groove 51 may have a non-polar surface of nitride or a semi-polar surface of nitride. Thus, 2DEG in a hetero junction in the nitride channel layer 4 or in the nitride barrier layer 5 may be interrupted. Therefore, when the gate voltage is zero, the carrier density in the gate region may be minimized.

The dielectric layer 10 may cover the nitride barrier layer 5 and include at least one of silicon nitride (SiN), silicon carbon nitride (SiCN), silicon dioxide (SiO₂), silicon aluminum nitride (SiAlN), Al₂O₃, aluminum oxynitride (AlON), silicon oxynitride (SiON), hafnium oxide (HfO₂) or the like. The dielectric layer 10 may be grown in-situ or be manufactured by ALD, chemical vapor deposition (CVD), MBE, plasma-enhanced chemical vapor deposition (PECVD) or low pressure chemical vapor deposition (LPCVD). The dielectric layer 10 may serve as a passivation layer.

The gate 8 is formed on a portion of the dielectric layer 10 which is above the gate region, where at least a portion of the gate 8 is formed in the groove 41 and the gate 8 has a “T” shape. Generally, the gate 8 and the nitride barrier layer 5 constitute a metal insulator semiconductor (MIS) structure or a metal oxide semiconductor field effect transistor (MOSFET) structure.

The source electrode 6 and the drain electrode 7 may be formed in a source electrode region and a drain electrode region, respectively, and form an Ohmic contact with the nitride barrier layer 5.

In some embodiments, the groove 41 may be rectangular. In other embodiments, the groove 41 may take other shapes, such as a triangle, trapezoid, serration, polygon, semicircle, “U” shape, or any combination thereof.

FIG. 7 schematically illustrates a cross-sectional view of an enhancement-mode device according to another embodiment of the present disclosure. As shown in FIG. 7, the enhancement-mode device is an epitaxial multilayer structure formed on a substrate. The broken line in FIG. 7 represents that the substrate under the epitaxial multilayer structure may take any suitable shape.

In some embodiments, the substrate may include sapphire, SiC, Si, LiNbO₃, SOI, GaN or AlN. Other layers, such as a nitride nucleation layer and/or a nitride buffer layer, may be formed on the substrate to be used to deposit a nitride semiconductor device. In some embodiments, the nitride nucleation layer may include AlN, GaN, AlGaN and etc. The nitride buffer layer may include AlGaN.

The epitaxial multilayer structure may include a nitride channel layer 4 and a nitride barrier layer 5 successively formed on the substrate. A gate region and two Ohmic contact regions are formed on the epitaxial multilayer structure, and the two Ohmic contact regions are on two sides of the gate region. The gate region is adapted to deposit a gate 8 and the two Ohmic contact regions are adapted to deposit a source electrode 6 and a drain electrode 7.

The nitride channel layer 4 and the nitride barrier layer 5 may be similar with those in the embodiments described above, which is not described in detail here.

The gate 8 is formed on the gate region. Different from the embodiments described above, the gate 8 in this embodiment is formed on the nitride barrier layer 5 and forms a Schottky contact with the nitride barrier layer 5.

The source electrode 6 and the drain electrode 7 form an Ohmic contact with the nitride barrier layer 5.

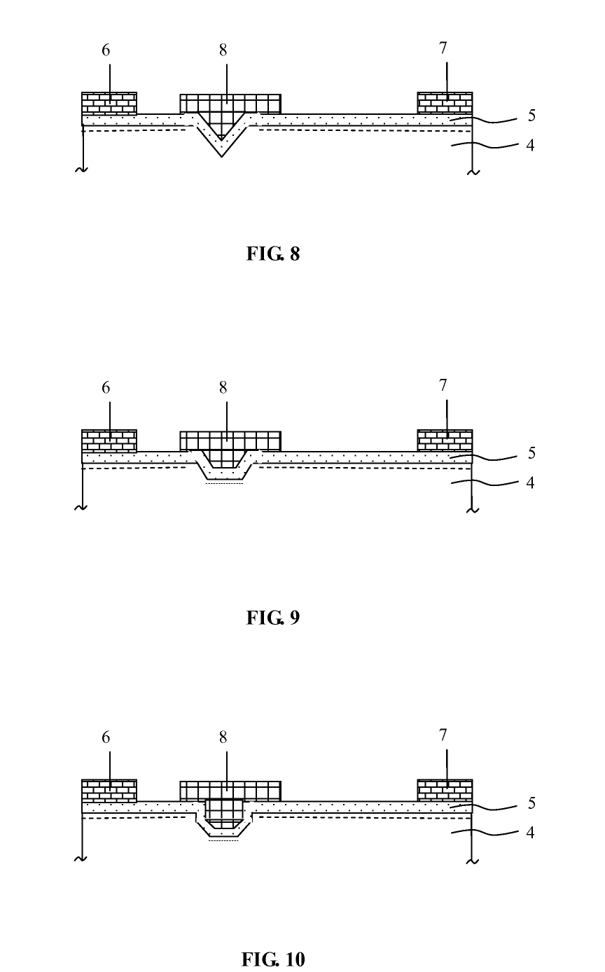

FIG. 8 schematically illustrates a cross-sectional view of an enhancement-mode device according to another embodiment of the present disclosure, wherein a groove in a gate region of the enhancement-mode device has a triangular cross-section. A semi-polar surface of nitride is generated by forming a triangular groove in the gate region.

FIG. 9 schematically illustrates a cross-sectional view of an enhancement-mode device according to another embodiment of the present disclosure, wherein a groove in a gate region of the enhancement-mode device has a trapezoidal cross-section. A trapezoidal groove is formed in the gate region to generate a semi-polar surface of nitride on a side wall of the trapezoidal groove.

FIG. 10 schematically illustrates a cross-sectional view of an enhancement-mode device according to another embodiment of the present disclosure, wherein a section of a groove in a gate region has a shape of a combination of a rectangle and a trapezoid. A non-polar surface is generated on a side wall of the rectangle and a semi-polar surface of nitride is generated on a side wall of the trapezoidal groove.

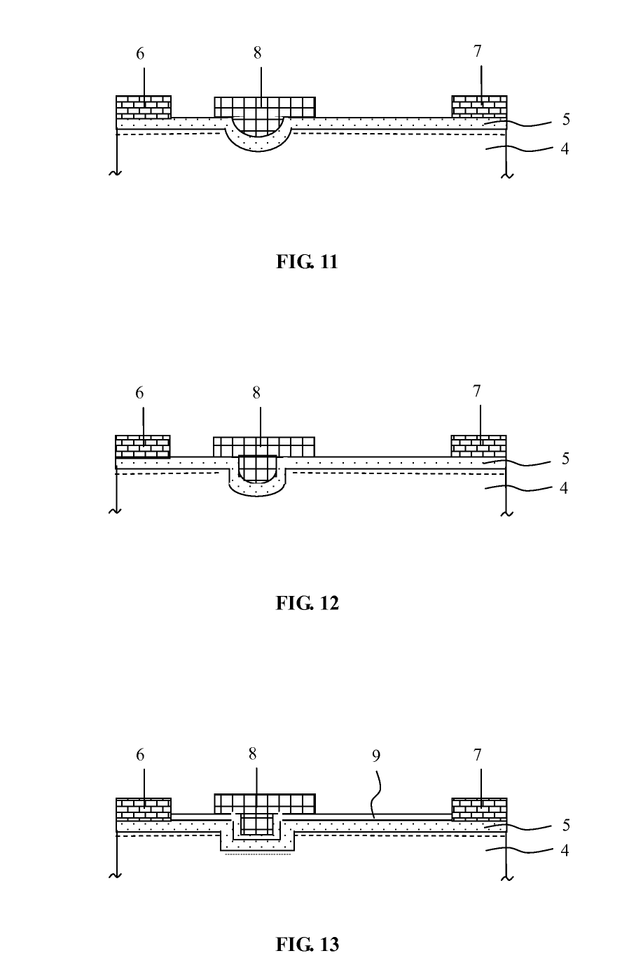

FIG. 11 schematically illustrates a cross-sectional view of an enhancement-mode device according to another embodiment of the present disclosure, wherein a groove in a gate region of the enhancement-mode device has a semicircular cross-section. A side wall of the semicircular groove changes from a non-polar surface to a semi-polar surface or even a polar surface gradually.

FIG. 12 schematically illustrates a cross-sectional view of an enhancement-mode device according to another embodiment of the present disclosure, wherein a groove in a gate region of the enhancement-mode device has a “U” shaped cross-section. A side wall of the “U” shaped groove changes from a non-polar surface to a semi-polar surface or even a polar surface gradually.

FIG. 13 schematically illustrates a cross-sectional view of an enhancement-mode device according to another embodiment of the present disclosure. As shown in FIG. 13, the enhancement-mode device is an epitaxial multilayer structure formed on a substrate. The broken line in FIG. 13 represents that the substrate under the epitaxial multilayer structure may take any suitable shape.

In some embodiments, the substrate may include sapphire, SiC, Si, LiNbO₃, SOI, GaN or AlN. Other layers, such as a nitride nucleation layer and/or a nitride buffer layer, may be formed on the substrate to be used to deposit a nitride semiconductor device. In some embodiments, the nitride nucleation layer may include AlN, GaN, AlGaN and etc. The nitride buffer layer may include AlGaN.

The epitaxial multilayer structure may include a nitride channel layer 4, a nitride barrier layer 5 and a nitride cap layer 9 successively formed on the substrate. A gate region and two Ohmic contact regions are formed on the epitaxial multilayer structure and the two Ohmic contact regions are on two sides of the gate region. The gate region is adapted to deposit a gate 8 and the two Ohmic contact regions are adapted to deposit a source electrode 6 and a drain electrode 7.

Different from the above embodiments, in this embodiment, the nitride cap layer 9 is formed on the nitride barrier layer 5. The nitride cap layer 9 may include GaN. The gate 8 is formed on the nitride cap layer 9.

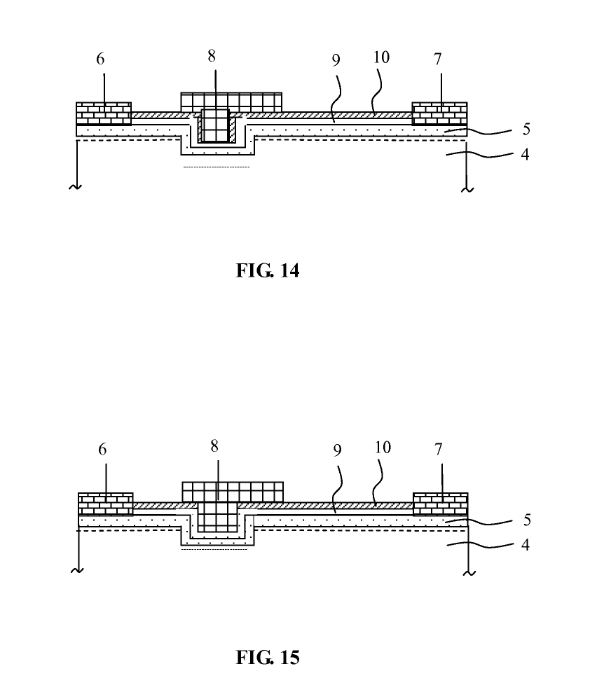

FIG. 14 schematically illustrates a cross-sectional view of an enhancement-mode device according to another embodiment of the present disclosure. As shown in FIG. 14, the enhancement-mode device is an epitaxial multilayer structure formed on a substrate. A broken line in FIG. 14 represents that the substrate under the epitaxial multilayer structure may take any suitable shape.

In some embodiments, the substrate may include sapphire, SiC, Si, LiNbO₃, SOI, GaN or AlN. Other layers, such as a nitride nucleation layer and/or a nitride buffer layer, may be formed on the substrate to be used to deposit a nitride semiconductor device. In some embodiments, the nitride nucleation layer may include AlN, GaN, AlGaN and etc. The nitride buffer layer may include AlGaN.

The epitaxial multilayer structure may include a nitride channel layer 4, a nitride barrier layer 5, a nitride cap layer 9 and a dielectric layer 10 successively formed on the substrate. A gate region and two Ohmic contact regions are formed on the epitaxial multilayer structure and the two Ohmic contact regions are on two sides of the gate region. The gate region is adapted to deposit a gate 8 and the two Ohmic contact regions are adapted to deposit a source electrode 6 and a drain electrode 7.

Different from the above embodiments, in this embodiment, the nitride cap layer 9 is formed on the nitride barrier layer 5 and the dielectric layer 10 is further formed on the nitride cap layer 9. The nitride cap layer 9 may include GaN. The dielectric layer 10 may include at least one of SiN, SiCN, SiO₂, SiAlN, Al₂O₃, AlON, SiON, HfO₂ or the like. The dielectric layer 10 may be grown in-situ or be deposited by ALD, CVD, MBE, PECVD or LPCVD. The gate 8 is formed on the dielectric layer 10.

FIG. 15 schematically illustrates a cross-sectional view of an enhancement-mode device according to another embodiment of the present disclosure. As shown in FIG. 15, the enhancement-mode device is an epitaxial multilayer structure formed on a substrate. A broken line in FIG. 15 represents that the substrate under the epitaxial multilayer structure may take any suitable shape.

In some embodiments, the substrate may include sapphire, SiC, Si, LiNbO₃, SOI, GaN or AlN. Other layers, such as a nitride nucleation layer and/or a nitride buffer layer, may be formed on the substrate to be used to deposit a nitride semiconductor device. In some embodiments, the nitride nucleation layer may include AlN, GaN, AlGaN or the like. The nitride buffer layer may include AlGaN.

The epitaxial multilayer structure may include a nitride channel layer 4, a nitride barrier layer 5, a nitride cap layer 9 and a dielectric layer 10 successively formed on the substrate. A gate region and two Ohmic contact regions are formed on the epitaxial multilayer structure and the two Ohmic contact regions are on two sides of the gate region. The gate region is adapted to deposit a gate 8 and the two Ohmic contact regions are adapted to deposit a source electrode 6 and a drain electrode 7.

Different from the above embodiments, in this embodiment, a portion of the dielectric layer 10 in the gate region is removed to enable the gate 8 to contact with the nitride cap layer 9, so that the gate 8 forms a Schottky contact with the nitride cap layer 9.

To sum up, an enhancement-mode device is provided. By employing a spontaneous polarization effect and a piezoelectric effect of nitride, a non-polar surface or a semi-polar surface, which has a direction opposite to that of a polar surface, is formed on a nitride channel layer, so that 2DEG in a groove is well controlled and a carrier density under the condition of a zero gate voltage is minimized. Furthermore, a plasma etching process is not required to be performed to a barrier layer, thereby avoiding degradation in device performance caused by damage of an active region, such as a low current density or a current collapse effect. Further, no magnesium atom is needed to form p-type nitride, thereby avoiding pollution to a MOCVD chamber or a MBE chamber.

Although the present disclosure has been disclosed above with reference to preferred embodiments thereof, it should be understood that the disclosure is presented by way of example only, and not limitation. Those skilled in the art can modify and vary the embodiments without departing from the spirit and scope of the present disclosure.

1. An enhancement-mode device which is an epitaxial multilayer structure formed on a substrate, comprising:
a nitride channel layer and a nitride barrier layer successively formed on the substrate;
a groove having a non-polar surface or a semi-polar surface formed in the epitaxial multilayer structure, resulting in at least a portion of two-dimensional electron gas in the epitaxial multilayer structure being interrupted;
a gate region defined by the groove and two Ohmic contact regions, wherein the two Ohmic contact regions are on two opposite sides of the gate region;
a gate formed in the gate region;
a source electrode and a drain electrode in the two Ohmic contact regions; and
a dielectric layer formed on the nitride barrier layer.

2. (canceled)

3. The enhancement-mode device according to claim 1, wherein the dielectric layer comprises one selected from silicon nitride, silicon carbon nitride, silicon dioxide, silicon aluminum nitride, aluminum oxide, aluminum oxynitride, silicon oxynitride and hafnium oxide, or any combination thereof.

4. The enhancement-mode device according to claim 1, further comprising a nitride cap layer formed on the nitride barrier layer, the nitride cap layer comprising gallium nitride or aluminum gallium nitride.

5. The enhancement-mode device according to claim 1, further comprising an aluminum nitride layer formed between the nitride channel layer and the nitride barrier layer.

6. The enhancement-mode device according to claim 1, wherein a section of the groove takes a shape of rectangle, triangle, trapezoid, serration, polygon, semicircle, “U” shape, or any combination thereof.

7.-9. (canceled)

10. The enhancement-mode device according to claim 1, further comprising a nitride nucleation layer and/or a nitride buffer layer formed on the substrate.

11. The enhancement-mode device according to claim 1, wherein the substrate comprises sapphire, silicon carbide, silicon, lithium niobate, silicon on insulator, gallium nitride or aluminum nitride.
